(19) United States
(12) Patent Application Publication
(10) Pub. No.: US 2026/0005074 A1
(43) Pub. Date: Jan. 1, 2026

(54) REAL-TIME COMPUTER VISION END-POINT DETECTION PIPELINE

(71) Applicant: Inficon Inc., East Syracuse, NY (US)

(72) Inventors: Anthony J. Vasquez, Fulton, NY (US); Kyle A. Drake, Syracuse, NY (US); Chunhua Song, Jamesville, NY (US)

(21) Appl. No.: 19/252,802

(22) Filed: Jun. 27, 2025

Related U.S. Application Data
(60) Provisional application No. 63/665,679, filed on Jun. 28, 2024.

(51) Int. Cl. H01L 21/66; H01L 21/67

(52) U.S. Cl. CPC H01L 22/26; H01L 21/67253

(57) ABSTRACT

A semiconductor etching process end-point detection system includes a sensor configured to measure in real-time electrical properties associated with a semiconductor etching process and to generate raw sensor data, and a computing device configured to receive the raw sensor data. The computing device includes spectrum analyzer circuitry and a memory configured to execute instructions of the spectrum analyzer circuitry via at least one processor. The instructions include obtaining, via the sensor, the raw sensor data; receiving, at the computing device, the raw sensor data; preprocessing the raw sensor data to normalize the raw sensor data to a standard range or distribution; selecting at least one best scoring signal of the normalized sensor data; converting the at least one best scoring signal to a pixel space; and performing an end-point prediction algorithm on the pixel space to predict the end-point of the semiconductor etching process.

### FIELD OF THE INVENTION

The present technology relates to semiconductor etching. In particular, the present invention relates to a system and method for detecting end-point for semiconductor etching process.

### BACKGROUND OF THE INVENTION

Deposition and etch processes at semiconductor manufacturing plants are widely and commonly being used during device fabrication in the semiconductor integrated circuit industry. The semiconductor industry efforts to reduce the dimensions, which traditionally were limited by the lithography resolution of 2-dimensional structures, are shifting to deposition and etch process control of 3-dimensional structures (for example, 3D gate and 3D NAND). Device critical dimensions are impacted more and more by the ability to control deposition and etch processes. With that being said, new technologies to allow tighter process control at etch and deposition processes are needed.

Plasma etch processes are often used to remove dielectrics, semiconductors, or metal layers by an ignition gas at a plasma state (which drive the activation energy of the chemical reaction). The material removal can also be performed by flowing reactive gases (in a non-plasma state) or through wet etch (at liquid state) stations. Deposition of films over the chamber components and the processed substrates can be applied by various methods like Plasma enhanced (PE) chemical vapor deposition (CVD), Sub atmospheric CVD, Thermal CVD, Atomic layers deposition (ALD), Plasma-enhanced atomic layer deposition and more. Etch and deposition processes can be isotropic or anisotropic (like Reactive Ion etching-RIE) depending upon the process step.

In substrate deposition processes, such as IC fabrication processes, deposition of many different layers over the wafer (which is the substrate) can be achieved through different reactions and various process matter states. Example technologies include plasma (PECVD and high-density plasma-HDP), gas-sub-atmospheric CVD (SACVD) and liquid (electroplating). Some of the examples for key parameters to control the deposited layers and the device fabrication characteristics are thickness, stress, mass, resistance, particles and refractive index. Those parameters are measured and controlled, not just for the mean value (over a wafer or a batch of wafers), but also wafer variability and interstitial wafers variability. Reducing the process variability contributes to the improvement of the manufacturing yield at the end of line (EOL) process.

For example, the following steps are used in substrate etching: wafer etching steps to apply patterns (in conjunction with lithography steps) to the manufactured device; cleaning the wafers from contamination; creating trenches between transistors; enabling separation between contacts and isolators; reacting the wafers surface before deposition and for removal of photo resist. Key parameters to control the etch process over the wafers are critical dimensions for the defined features, such as etch rate, thickness, stress, particles and defect control and other electrical and optical parameters.

Substrate etch and deposition may or may not be simultaneous processes (for example, in some of the HDP processes, etch and deposition may occur consecutively or concurrently) in the same process chamber, consecutively in the chamber, non-sequentially in the chamber or in different chambers.

Some of the process steps, before or after the deposition step (over the wafers), may include pre- or post-treatment to etch the wafer surface. For example, pretreatment (before deposition) involves removal of contaminants from the wafer surface so as to facilitate better adhesion of the deposited layer, and post-treatment to anneal, or to “shrink”, the deposited layer. During those processes, by-products removed from the substrates may stick to, and deposit, the chamber components and/or etch different chamber components. For example, during plasma pretreatment of the substrate, by-products may be deposited on the chamber wall but removed from the chamber chuck (where the wafer is seated).

Post-maintenance deposition and etch, including post preventive or reactive maintenance of the process chamber, deposition and etch cycles with, and/or without, substrates would apply to allow better particle performance, process uniformity (within or/and between substrates), process con-trol and rate control. In this process, by-products may be deposited or removed (etched) from different chamber components.

During plasma or chemical etching processes, precise control over material removal is critical to device performance. Detection of the end-point in semiconductor etching processes is an important step in ensuring precision and yield during microfabrication. The end-point detection refers to the moment when the etching process has removed just the right amount of material, typically stopping at an interface or desired depth, such as a specific layer. The end-point detection is important to prevent over-etching, to avoid under-etching and to ensure uniformity and repeatability across wafers. Various end-point detection techniques are utilized, including optical emission spectroscopy, laser interferometry, mass spectroscopy, electrical (RF) sensors, and vacuum gauges.

As semiconductor manufacturing progresses to smaller technology nodes, maintaining manufacturing yield requires higher precision and more stable processes. Maintaining these processes requires sensors advanced enough to detect minute changes in process and control systems that can respond to sensor output and changing tool conditions in real-time or on a run-by-run (“RbR”) basis. Artificial intelligence and machine learning (“AI/ML”) models are enabling the use of more advanced sensors and the processing of higher volumes of data. However, conventionally, these models are applied on central computing servers, which precludes time-sensitive applications.

Detecting end-point in low open area etch processes is difficult because sensors conventionally used for end-point detection lack necessary sensitivity. More sensitive sensor technologies produce signals too complex for manual human interpretation. Thus, most of these etch processes rely on timed recipes, increasing the risk of process faults and decreasing uniformity, which limits chip quality and effectiveness. Traditionally, end-point detection relies on individual sensor signals or a combination of a small number of individual signals. Univariate approaches do not take full advantage of the multivariate sensor output. For many sensors, every unique plasma recipe requires a unique univariate solution.

Further, the known real-time detection systems and methods are not currently used for RF signals generated by an electric field (E-field) and/or magnetic field (B-Field) antenna configurations in real-time.

What is needed, therefore, is an improved semiconductor etching process end-point detection technique that addresses at least the problems described above.

### SUMMARY OF THE INVENTION

According to an example embodiment of the present technology, a semiconductor etching process end-point detection system is provided. The system includes at least one sensor configured to measure in real-time at least one of electric properties and magnetic properties associated with a semiconductor etching process and to generate raw sensor data, and a computing device configured to receive the raw sensor data. The computing device includes spectrum analyzer circuitry and a memory configured to execute instructions of the spectrum analyzer circuitry via at least one processor. The instructions include obtaining, via the sensor, the raw sensor data; receiving, at the computing device, the raw sensor data; preprocessing the raw sensor data including at least one of normalizing the raw sensor data and standardizing the raw sensor data; selecting a plurality of best scoring signals of the preprocessed sensor data; converting the plurality of best scoring signals to a pixel space; and performing an end-point prediction algorithm on the pixel space to predict the end-point of the semiconductor etching process.

In some embodiments, the instructions further include determining an end-point threshold for ending the semiconductor etching process based on the end-point prediction. In certain of these embodiments, determining the end-point threshold includes performing at least one thresholding technique configured to improve robustness of the end-point prediction.

In some embodiments, the sensor includes at least one of an E-field antenna and an B-field antenna, and the raw sensor data comprises RF signals.

In certain embodiments, selecting the plurality of best scoring signals includes applying a signal selection filter to the preprocessed sensor data to determine a base signal. In some of these embodiments, the signal selection filter utilizes power spectral entropy to determine the base signal. In additional embodiments, selecting the plurality of best scoring signals further includes applying a similarity filter to the base signal and the preprocessed sensor data to determine the plurality of best scoring signals. In further embodiments, the similarity filer measures distance between the base signal and all other signals to determine the plurality of best scoring signals.

In some embodiments, the pixel space is an unsigned integer datatype pixel-matrix.

In some cases, a machine learning module is also provided including a trained model, the machine learning module configured to receive the pixel space and generate an end-point prediction output based on the trained model.

According to an additional example embodiment of the present technology, an end-point detection system is provided. The system includes at least one sensor configured to measure in real-time at least one of electric properties and magnetic properties associated with a semiconductor etching process and to generate raw sensor data, and a computing device configured to continuously receive the raw sensor data. The computing device includes a spectrum analyzer circuitry and a memory configured to execute instructions via at least one processor. The instructions include obtaining, via the at least one sensor, the raw sensor data; receiving, at the computing device, the raw sensor data; selecting at least one best scoring signal of the raw sensor data; converting the at least one best scoring signal to a pixel space; and performing an end-point prediction algorithm on the pixel space to predict the end-point.

According to a further embodiment of the present technology, a method for end-point detection for a semiconductor etching process is provided. The method includes continuously measuring, via a sensor, at least one of electric properties and magnetic properties associated with the semiconductor etching process and generating raw sensor data; receiving, by a computing device, the raw sensor data; preprocessing, by the computing device, the raw sensor data; selecting, by the computing device, a plurality of best scoring signals of the preprocessed sensor data; converting, by the computing device, the plurality of best scoring signals to a plurality of pixel spaces; and performing, by the computing device, an end-point prediction algorithm on the plurality of pixel spaces to predict the end-point of the semiconductor etching process. The computing device includes spectrum analyzer circuitry and a memory configured to perform the steps via at least one processor.

In some embodiments, the sensor includes at least one of an E-field antenna and an B-field antenna, and the raw sensor data comprises RF signals.

In certain embodiments, each of the plurality of pixel spaces is an unsigned integer datatype pixel-matrix.

In some embodiments, the method also includes determining, via the computing device, an end-point threshold for ending the semiconductor etching process based on the end-point prediction.

In certain embodiments, selecting the plurality of best scoring signals includes applying a signal selection filter to the preprocessed sensor data to determine a base signal. In some of these embodiments, applying the signal selection filter includes calculating power spectral entropy of the preprocessed sensor data and determining the base signal based on a lowest entropy value. In additional embodiments, selecting the plurality of best scoring signals further includes applying a similarity filter to the base signal and the preprocessed sensor data to determine the plurality of best scoring signals. In further embodiments, applying the similarity filer includes measuring distance between the base signal and all other signals to determine the plurality of best scoring signals based on a shortest distance.

In some embodiments, the method also includes receiving the plurality of pixel spaces via a machine learning module with a trained model and generating an end-point prediction output based on the trained model.

The foregoing and other aspects, features, and advantages of the application will become more apparent from the following description and from the claims.

### BRIEF DESCRIPTION OF THE DRAWINGS

The features of the application can be better understood with reference to the drawings described below, and the claims. The drawings are not necessarily to scale, emphasis instead generally being placed upon illustrating the principles described herein. In the drawings, like numerals are used to indicate like parts throughout the various views.

FIG. 1 is a schematic illustration of a chamber for semiconductor processing with a sensor according to some embodiments of the present technology.

FIG. 2 is a flowchart showing the data pipeline overview according to some embodiments of the present technology.

FIG. 3 is a chart showing a pixel space representation of selected features according to some embodiments of the present technology.

### DETAILED DESCRIPTION OF THE INVENTION

Embodiments of the present technology disclosed herein are directed to systems and methods for deploying AI/ML models at the edge for real-time and RbR applications. In some embodiments, through integration of the low-latency Libtorch library with INFICON's FabGuard® technology, state-of-the-art solutions developed using PyTorch are implemented at the edge. This design not only extends the capabilities of FabGuard® for real-time analysis and fault detection classification methods, but also provides an interface for users to deploy third-party models. Thus, machine-learning professionals can develop and train models externally in Python and then deploy them in FabGuard®. AI/ML models discussed herein are configured to extract relevant information for end-point detection in complex multivariate signals without per recipe configuration, only requiring timed parameters. The drawing figures discussed below demonstrate the output of a sensor and the output of a model using the sensor data to predict etch end-point for a low open area process. In some embodiments, the system is coded and trained in Python, while FabGuard® system is used to acquire sensor data, load the trained system, and predict end-points on out-of-sample etch data.

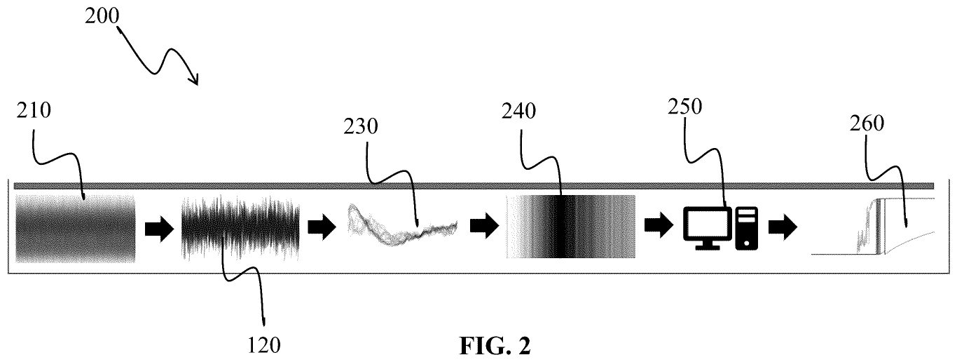

As shown in FIG. 2, systems and methods 200 of the present technology include receiving raw sensor data 210. The raw sensor data can come from many sources, and any different types of sensors may be employed in the present disclosure. Combinations of any of the following sensor types may be used as a sensor in one or more embodiments: Quartz Crystal Microbalance (QCM) sensors, microelectromechanical (MEM) sensors, capacitor sensors, photocathodes, photo detector sensors, micro machined ultrasonic transducers, oscillator devices configured to measure energy or mass changes, resonance electro/optical devices, resistance measurement sensors, sensors having a dielectric waveguide in contact with a metallic layer or a metallic pattern suitable to generate a Plasmonic reaction, light emitting devices, electron beam sources, ultrasonic sources, optical resonators, micro-ring resonators, photonic crystal structure resonators, temperature sensors. A person of ordinary skill in the art would readily understand how these types of sensors are made and used. In some embodiments, the raw sensor data comes from one or more sensors used with spectrometers that measure spectra as a function of time. The present disclosure makes use of a variety of such sensors positioned at different locations in the process chamber and/or directly outside the chamber. In some exemplary embodiments, raw sensor data includes RF signals generated by an electric field (E-field) and/or magnetic field (B-Field) antenna configurations. The raw E/B RF sensor data contains information relating to real-time changes in plasma conditions, plasma behavior, chamber conditions, and wafer interaction.

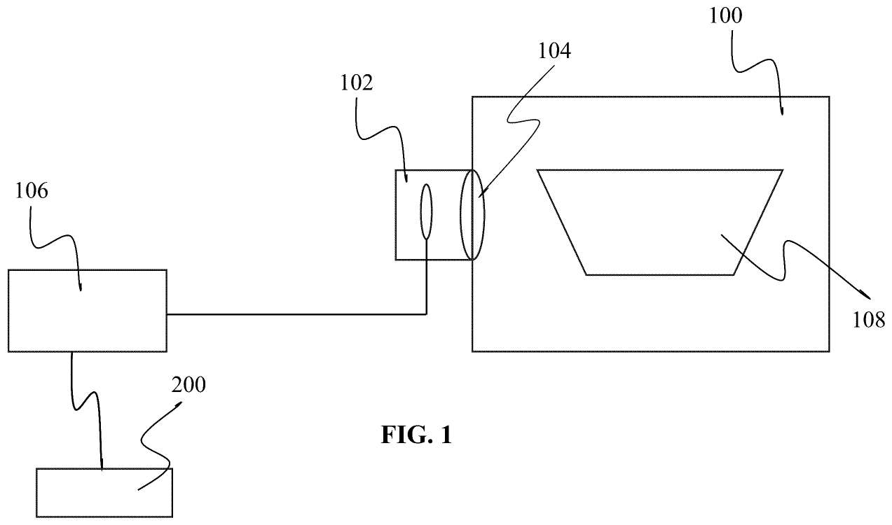

FIG. 1 schematically illustrates an exemplary chamber 100 for semiconductor processing with a sensor 102. In some embodiments, the sensor is INFICON Radio Acquisition Device sensor (IRAD). In some embodiments, the sensor 102 is configured for a non-invasive installation, as shown in FIG. 1. The sensor 102 is mounted externally on the chamber's view port 104 and is electrically or electronically connected to an RF electronics box 106 (RF spectrum analyzer). In this non-invasive embodiment, the sensor 102 avoids direct contact with the plasma 108 or internal processes, which ensures independent operation of the sensor 102 without introducing risks of interference or contamination. Additionally, this non-intrusive installation eliminates the need for any modifications to the chamber hardware, streamlining the deployment process and significantly reducing downtime.

The sensor 102 is configured to monitor electromagnetic waves emitted by a radio frequency (RF) source. When certain conditions in the chamber 100 change, they can disrupt the even distribution of RF power, leading to localized accumulation of electric charge. This, in turn, alters the intensity of the local electric field. As the charge builds up and the electric field strength increases, the charge may reach a critical threshold, triggering minor discharges or electromagnetic radiation. The sensor 102 is configured to detect and capture these subtle, gradual increases in electric field intensity. The sensor 102 may include an antenna and one or more shielding boxes. The antenna is configured to capture electrical signals emitted by the plasma 108, such as RF emissions and variations in plasma intensity.

The RF electronics 106 (spectrum analyzer) is configured to process and interpret the signals captured by the sensor 102 antenna. In some embodiments, the RF spectrum analyzer 106 is configured to interface with PC-based control software 110 in order to aggregate, visualize, and analyze data. In some embodiments, the PC-based control software may include INFICON FabGuard® system. The software is configured to transform the signals detected by the sensor 102 into meaningful visual representations, providing detailed plots that offer insights into plasma behavior, changes in process conditions, and end-point detection. This comprehensive visualization aids in real-time monitoring and facilitates efficient decision-making during semiconductor manufacturing processes. Any other type of controller may be used in the present technology. The controller may include a processor, memory, software logic, hardware logic and input and output subsystems from communicating with, monitoring and controlling a plasma processing system. The controller may also handle processing of one or more recipes including multiple set points for various operating parameters (e.g., voltage, current, frequency, pressure, flow rate, power, temperature, etc.), e.g., for operating a plasma processing system. In some embodiments, the controller may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer.

In some embodiments, the sensor produces 25K raw signals emanating from etch/deposition processes. Only 1K signal bins are shown in the Raw Sensor Data block 210 of FIG. 1 because attempting to predict on end-point on 25K seemingly stochastic raw signals is an Np-Hard problem. For example, using a neural network to learn useful representations requires a sophisticated network, which would effectively require tens of millions of trainable parameters. Training this network would be time-consuming and compute heavy. However, what makes this approach infeasible is real-time inference, since the large architecture needs to operate on large input data, which means that inferencing <1.0s per timestep is impractical. In preferred embodiments, 1K signal bins are used by the system.

Another issue is that a neural network cannot always be used to extract useful features and generalize without biasing towards noisy data. The majority of the data is noisy and often interfered with. This means that most data that a model sees is of low signal-to-noise ratio (“SNR”) with potentially high-interference. Harder still, is that the noise and interference also effect the useful data. In other words, there is more un-useful than useful data for the model to generalize to. For that reason, steps to enhance the signal yet still maintain important features are needed.

As shown in FIG. 2, the systems and methods 200 of the present technology may include data preprocessing 220, which may include data standardization and/or data normalization. Data standardization transforms the raw sensor data received from the sensor(s) to have zero mean and unit variance to help AI/ML models perform better by removing scale differences across variables. In some embodiments, the data standardization includes a data preprocessing technique to normalize the raw sensor data to a standard range or distribution per Equation 1 below:

$${X}^{′} = \frac{X - μ}{σ} \qquad Equation 1$$

where X is the data and μ and σ are the mean and standard deviations of the data respectively. Data normalization rescales the data to a fixed range—usually [0, 1] or [0, 255]. In some embodiments, the data normalization includes a data preprocessing technique to rescale the data to a fixed range per Equation 2 below:

$${x}_{norm} = \frac{x - {x}_{min}}{{x}_{max} - {x}_{min}} \qquad Equation 2$$

where x is the original value being normalized (a single point in a spectral signal); xₘᵢₙ is the minimum value in the entire dataset (or spectrum), which becomes 0 after normalization; xₘₐₓ is the maximum value in the dataset, which becomes 1 after normalization; and xₙₒᵣₘ is the normalized value corresponding to the original x, which lies between 0 and 1 after transformation. The steps of data normalization and data standardization may be performed in any order.

As shown in FIG. 2, the systems and methods 200 of the present technology further include signal selection 230. In some embodiments, the Power Spectral Entropy (“PSE”) is used as a signal selection filter for measuring if a signal is forecastable. Theoretically, a purely stochastic signal yields a high entropy score, which means that past knowledge of the state of the signal does not contribute to knowledge of the future state of the signal. An arbitrary number of signals with the lowest entropy score are selected using PSE (or highest PSE-score depending on equation and data configuration). In some embodiments, the PSE is calculated by using Shannon Entropy per Equation 3 below:

$$PSE = - {\sum }_{f = 0}^{f = \frac{{f}_{s}}{2}} P ( f ) {log}_{2} [ P ( f ) ] \qquad Equation 3$$

where ƒₛ is the sampling frequency, and P is the power spectral density. A Fast Fourier Transform, or another suitable computation method, may be used to compute frequency components of the signals. In some embodiments, about 1024 signals with the lowest entropy score are selected during this step.

After an arbitrary number of signals are selected from the PSE filter, the signals may need to be further processed because not all signals are useful. In some embodiments, a similarity filter is used as a further feature reduction mechanism to effectively enhance the best scoring PSE signals. The best scoring PSE having the lowest entropy score is used as a base signal. The distance of all other signals is measured against the base signal, and an arbitrary number of largest distanced signals are removed. In some embodiments, the similarity metric used is the straight-line distance, otherwise known as the Euclidean distance, as shown in Equation 4 below:

$$d = \sqrt{{( {x}_{2} - {x}_{1} )}^{2} + {( {y}_{2} - {y}_{1} )}^{2}} \qquad Equation 4$$

where x₁, y₁ and the coordinates of the first point, and x₂, y₂ are the coordinates of the second point. Other embodiments may use different distance equations, such as the Mahalanobis, Manhattan, Minkowski, and cosine distances. In some embodiments, about 256 signals that are most similar to the signal with the lowest entropy are selected during this step.

Other signal selection methods may be implemented in accordance with the present invention. In some embodiments, a filter using mean amplitude or standard deviation calculated over a subset of the run time may be used to select a subset of signals. The time varying signals are divided into smaller segments—i.e., subsets of run time—and each segment is analyzed separately using statistical tools. For example, a mean amplitude and/or a standard deviation of the signals in each subset is calculated. This information is then used to filter the signals and determine which signals will be used for processing. A similarity filter as discussed above may be used as the next step to further filter out the signals. Frequency bins adjacent to the selected bins may also be included. In additional embodiments, a priori knowledge of the spectrum may be used to select bins and adjacent bins may be used as well.

As shown in FIG. 2, systems and methods of the present technology include pixel conversion 240. After the signals are scored and selected, the signal bins are converted to pixel space. More particularly, the signals are normalized between 0-255 and converted to unsigned integer datatype (“UINT”). The pixel-matrix is a single channel image that is input to the machine learning model.

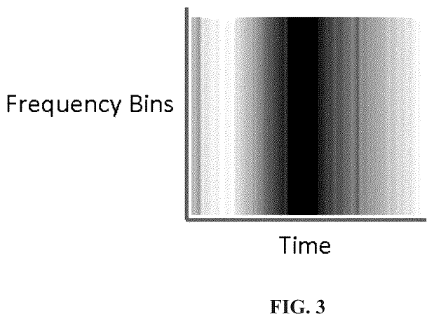

In some embodiments, the selected signals are packaged into a first-in-first-out queue of a configurable length beginning at a first point of the step of interest. For example, if the length is 100 steps, then step 101 removes point 0 (the first point in the queue). This queue becomes a matrix, as shown in FIG. 3, where rows are frequencies, and columns are observations (time). The matrix is a heatmap of amplitude vs. time for many frequencies, which can be readily analyzed with computer vision architectures. Each time a new scan is added to the queue, a new image is produced.

As shown in FIG. 2, systems and methods of the present technology further include input to custom trained machine learning (“ML”) algorithm 250. This may include both finetuning and training from scratch. For the finetuning task, a pretrained deep neural network (DNN), in particular Convolutional Neural Network (CNN) may be used. CNN is a type of deep neural network designed to analyze visual data, such as images, videos, or even time-series with spatial patterns. CNN operates with multiple layers between the input and output that automatically learn patterns from data. It typically includes an input layer that receives raw data (in this case, image pixels from the pixel conversion step 240), one or more hidden layers that extract increasingly abstract features (e.g., image edges, textures, shapes or objects), and an output layer that provides the final result (classification label or numeric prediction). CNN operates by multiplying the inputs it receives by a set of numbers (weights), adds a bias, and then passes the result through a non-linear activation function that decides whether and how much of that signal should move on to the next layer. Training a CNN involves minimizing a loss function-typically cross-entropy for classification or mean squared error for regression-using stochastic gradient descent (SGD) or its variants. The gradients of the loss with respect to the network's parameters are computed via backpropagation, which systematically applies the chain rule of calculus to efficiently compute partial derivatives across layers. Weights are updated iteratively to reduce the loss on a labeled dataset, ideally improving generalization to unseen data. Various CNN architectures may be used, including but not limited to ResNet (such as ResNet-18), Inception, Darknet, VGG, GoogleNet, RetinaNet, SimpleCNN, and others. ResNet-18 is a deep convolutional neural network with 18 layers that include learnable parameters. ResNet-18 incorporates residual blocks, which include skip connections that allow gradients to flow directly through the network, addressing the degradation problem in very deep neural network.

During development, the model trains on images of the format of FIG. 3 wherein X axis is time and Y axis is frequency. During deployment, the model is switched to inference mode and the heatmaps of FIG. 3 are model inputs for the task of image classification.

The heat map images may be normalized by row and smoothing filters may be convolved with the image. In some embodiments, a Gaussian filter is used on the images. The Gaussian filter reduces noise and detail in an image by averaging pixel values with their neighbors, with more weight given to pixels closer to the center. The Gaussian filter uses a kernel (small matrix) shaped like a 2D bell curve according to the 2D Gaussian function per Equation 5 below:

$$G ( x , y ) = \frac{1}{2 {πσ}^{2}} {e}^{- \frac{{x}^{2} + {y}^{2}}{2 {σ}^{2}}} \qquad Equation 5$$

wherein x and y represent the horizontal (x) and vertical (y) distances from the center of the Gaussian function (typically the center of a kernel), σ is a standard deviation that controls the spread or width of the bell-shaped curve (larger σ→wider, flatter Gaussian, smaller σ→narrower, sharper peak), and e is Euler's number (˜2.718).

In additional embodiments, edge detection filters are convolved with the image. Various edge detection filters may be used, including Sobel filter, Prewitt filter, Roberts Cross filter, Scharr filter, and Canny Edge detector. In some embodiments, the images are convolved with the Sobel filter, which uses two 3×3 convolution kernels (matrices) to approximate the derivatives of the image in both horizontal (x) and vertical (y) directions.

Next, each image is divided into sections and subsections where feature extraction and classification occur independently to identify and localize objects that look like an endpoint. More than one section of the image may be identified as endpoint objects, especially if the etch is complicated and/or if there are interfering signals. A tracking algorithm is used to maintain a list of endpoint objects and track them over time, declaring endpoint when the quantity and persistence of endpoint objects suggests that an endpoint has occurred.

Meaningful examples of process end-points are hand-picked from representations of the data after undergoing the pipeline of FIG. 2. Thousands of representations are generated and split into train, test, and validation sets. The trainset is used to train the architecture, and the samples are batched then sequentially augmented to aid generalization. Example augmentations include rotation, translation, scaling, smoothing, blurring, horizontal flipping, vertical flipping, jitter, random-contrast, pixel exclusion, etc. The validation set is used to monitor learning performance during training. Finally, the out-of-sample test set is used to understand how well the model generalized. These steps are repeated with multiple dataset splits and hyperparameter configurations until a high performing model is realized.

The mode of the trained model is then switched to inference, effectively forgoing backpropagation calculations and model weight updates. The trained model is used to predict new instances given raw E- and B-field data. The preprocessing, transformation, and prediction steps are rolled into a single model that follows the steps of FIG. 2.

As shown in FIG. 2, systems and methods of the present technology include end-point (“EP”) prediction 260. The trained model preferably only needs raw E- and B-field RF signal inputs to perform the flowchart steps outlined in FIG. 2. The probability of EP is the predicted output and is the threshold source from which EP policies and/or parameters are created.

Accordingly, embodiments of the present technology disclosed herein are directed to systems and methods of real-time detection pipelines of semiconductor etching processes via E/B Field RF-signals. Some embodiments use a specific data pipeline implementation that includes composite preprocessing and machine learning inference techniques to transform problem space to computer vision and output end-point signals given raw E/B Field RF signals.

Any software and/or firmware for performing the real-time detection pipelines of semiconductor etching processes via E/B Field RF-signals discussed herein can be provided on a computer readable non-transitory storage medium. A computer readable non-transitory storage medium as non-transitory data storage includes any data stored on any suitable media in a non-fleeting manner. Such data storage includes any suitable computer readable non-transitory storage medium, including, but not limited to hard drives, non-volatile RAM, SSD devices, CDs, DVDs, etc.

The term “about” is to be construed as modifying a term or value such that it is not an absolute. This term will be defined by the circumstances. This includes, at the very least, the degree of expected experimental error, technique error and instrument error for a given technique used to measure a value. In general, this term used in connection with a numerical value throughout the specification and the claims denotes an interval of accuracy, familiar and acceptable to a person skilled in the art. In general, such interval of accuracy is ±10%. Thus, “about ten” means 9 to 11. All numbers in this description indicating amounts, ratios of materials, physical properties of materials, and/or use are to be understood as modified by the word “about,” except as otherwise explicitly indicated.

The terms “a” and “an” do not denote a limitation of quantity, but rather denote the presence of at least one of the referenced item.

The term “or” means “and/or” unless clearly indicated otherwise by context. Reference throughout the specification to “an embodiment”, “another embodiment”, “some embodiments”, and so forth, means that a particular element (e.g., feature, structure, step, or characteristic) described in connection with the embodiment is included in at least one embodiment described herein, and may or may not be present in other embodiments. In addition, it is to be understood that the described elements may be combined in any suitable manner in the various embodiments.

“Optional” or “optionally” means that the subsequently described event or circumstance may or may not occur, and that the description includes instances where the event occurs and instances where it does not.

The terms “first,” “second,” and the like, “primary,” “secondary,” and the like, as used herein do not denote any order, quantity, or importance, but rather are used to distinguish one element from another.

The terms “front”, “back”, “bottom”, and/or “top” are used herein, unless otherwise noted, merely for convenience of description, and are not limited to any one position or spatial orientation.

The endpoints of all ranges directed to the same component or property are inclusive of the endpoints, are independently combinable, and include all intermediate points. For example, ranges of “up to 25 N/m, or more specifically 5 to 20 N/m” are inclusive of the endpoints and all intermediate values of the ranges of “5 to 25 N/m,” such as 10 to 23 N/m.

Unless defined otherwise, technical and scientific terms used herein have the same meaning as is commonly understood by one of skill in the art to which this invention belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While embodiments of the present disclosure have been particularly shown and described with reference to certain examples and features, it will be understood by one skilled in the art that various changes in detail may be effected therein without departing from the spirit and scope of the present disclosure as defined by claims that can be supported by the written description and drawings. Further, where exemplary embodiments are described with reference to a certain number of elements it will be understood that the exemplary embodiments can be practiced utilizing either less than or more than the certain number of elements.

What is claimed is:

1. A semiconductor etching process end-point detection system, comprising:
at least one sensor configured to measure in real-time at least one of electric properties and magnetic properties associated with a semiconductor etching process and to generate raw sensor data; and
a computing device configured to receive the raw sensor data, the computing device comprising spectrum analyzer circuitry and a memory configured to execute instructions of the spectrum analyzer circuitry via at least one processor, the instructions comprising:
obtaining, via the at least one sensor, the raw sensor data;
receiving, at the computing device, the raw sensor data;
preprocessing the raw sensor data comprising at least one of normalizing the raw sensor data and standardizing the raw sensor data;
selecting a plurality of best scoring signals of the preprocessed sensor data;
converting the plurality of best scoring signals to a pixel space; and
performing an end-point prediction algorithm on the pixel space to predict the end-point of the semiconductor etching process.

2. The system of claim 1, wherein the instructions further comprise determining an end-point threshold for ending the semiconductor etching process based on the end-point prediction.

3. The system of claim 2, wherein determining the end-point threshold comprises performing at least one thresholding technique configured to improve robustness of the end-point prediction.

4. The system of claim 1, wherein the sensor includes at least one of an E-field antenna and an B-field antenna, and the raw sensor data comprises RF signals.

5. The system of claim 1, wherein selecting the plurality of best scoring signals comprises applying a signal selection filter to the preprocessed sensor data to determine a base signal.

6. The system of claim 5, wherein the signal selection filter utilizes power spectral entropy to determine the base signal.

7. The system of claim 5, wherein selecting the plurality of best scoring signals further comprises applying a similarity filter to the base signal and the preprocessed sensor data to determine the plurality of best scoring signals.

8. The system of claim 7, wherein the similarity filer measures distance between the base signal and all other signals to determine the plurality of best scoring signals.

9. The system of claim 1, wherein the pixel space is an unsigned integer datatype pixel-matrix.

10. The system of claim 1, further comprising a machine learning module comprising a trained model, the machine learning module configured to receive the pixel space and generate an end-point prediction output based on the trained model.

11. An end-point detection system, comprising:
at least one sensor configured to measure in real-time at least one of electric properties and magnetic properties associated with a semiconductor etching process and to generate raw sensor data; and
a computing device configured to continuously receive the raw sensor data, the computing device comprising spectrum analyzer circuitry and a memory configured to execute instructions via at least one processor, the instructions comprising:
obtaining, via the at least one sensor, the raw sensor data;
receiving, at the computing device, the raw sensor data;
selecting at least one best scoring signal of the raw sensor data;
converting the at least one best scoring signal to a pixel space; and
performing an end-point prediction algorithm on the pixel space to predict the end-point.

12. A method for end-point detection for a semiconductor etching process, comprising:
continuously measuring, via a sensor, at least one of electric properties and magnetic properties associated with the semiconductor etching process and generating raw sensor data;
receiving, by a computing device, the raw sensor data;
preprocessing, by the computing device, the raw sensor data;
selecting, by the computing device, a plurality of best scoring signals of the preprocessed sensor data;
converting, by the computing device, the plurality of best scoring signals to a plurality of pixel spaces; and
performing, by the computing device, an end-point prediction algorithm on the plurality of pixel spaces to predict the end-point of the semiconductor etching process;
wherein the computing device comprises spectrum analyzer circuitry and a memory configured to perform the steps via at least one processor.

13. The method of claim 12, wherein the sensor comprises at least one of an E-field antenna and an B-field antenna, and the raw sensor data comprises RF signals.

14. The method of claim 12, wherein each of the plurality of pixel spaces is an unsigned integer datatype pixel-matrix.

15. The method of claim 12, further comprising determining, via the computing device, an end-point threshold for ending the semiconductor etching process based on the end-point prediction.

16. The method of claim 12, wherein selecting the plurality of best scoring signals comprises applying a signal selection filter to the preprocessed sensor data to determine a base signal.

17. The method of claim 16, wherein applying the signal selection filter comprises calculating power spectral entropy of the preprocessed sensor data and determining the base signal based on a lowest entropy value.

18. The method of claim 16, wherein selecting the plurality of best scoring signals further comprises applying a similarity filter to the base signal and the preprocessed sensor data to determine the plurality of best scoring signals.

19. The method of claim 18, wherein applying the similarity filer comprises measuring distance between the base signal and all other signals to determine the plurality of best scoring signals based on a shortest distance.

20. The method of claim 12, further comprising receiving the plurality of pixel spaces via a machine learning module comprising a trained model and generating an end-point prediction output based on the trained model.
